(19) United States
(12) Patent Application Publication
(10) Pub. No.: US 2005/0086565 A1
(43) Pub. Date: Apr. 21, 2005

(54) System and method for generating a test case

(76) Inventors: Ryan Clarence Thompson, Loveland, CO (US); John Warren Maly, Laporte, CO (US); Zachary Steven Smith, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/676,236

(22) Filed: Oct. 1, 2003

(51) Int. Cl. G06F 17/50; G01R 31/28; G06F 11/00

(52) U.S. Cl. 714/741

(57) ABSTRACT

A system and method for generating a test case operable to test a circuit design using a plurality of threads. In one embodiment, a test code and state initialization engine, responsive to a random number sequence and a probability profile, generates test code. A distribution settings engine generates default distribution settings that specify a magnitude of at least one simulation parameter for each thread based on a default probability distribution profile. A knob-setting interface is included for optionally differentiating the default distribution settings. The optionally differentiated distribution settings are then associated with the test code in order to generate the test case that exercises a circuit design model of the circuit design.

### CROSS-REFERENCE TO RELATED APPLICATION(S)

This application discloses subject matter related to the subject matter disclosed in the following commonly owned co-pending patent application: “System and Method for Testing a Circuit Design,” filed ______, application Ser. No. ______ (Docket Number 200209135-1), in the names of Ryan C. Thompson, John W. Maly, and Zachary S. Smith and “System and Method for Building a Test Case Including a Summary of Instructions,” filed ______, application Ser. No. ______ (Docket Number 200208930-1), in the names of Ryan C. Thompson, John W. Maly, and Adam C. Brown, both of which are hereby incorporated by reference for all purposes.

### BACKGROUND

The design cycle for a digital integrated circuit is long and expensive. Once the first chip is built, it is very difficult, and often impossible, to debug it by probing internal connections or to change the gates and interconnections. Usually, modifications must be made in the original design database and a new chip must be manufactured to incorporate the required changes. Since this process can take months to complete, chip designers are highly motivated to attempt to perfect the chip prior to manufacturing.

It is therefore essential to identify and quantify the architectural requirements necessary to assure good performance over a wide range of events prior to manufacturing the digital integrated circuit. Accordingly, a simulator comprising program code may be employed to provide a simulation environment that is executable on top of a host computer platform in order to model at least some or all of the functionalities of the desired integrated circuit, for example, a target processor core. The characteristics of the target processor core that the simulator emulates may be specified to include processor architectural model, processor clock speed, cache configuration, disk seek time, memory system bus bandwidth, and numerous other parameters. The resulting software-based target processor core provides the appearance of being a normal processor core while a test generator exercises the target processor core with test cases in order to collect detailed hardware behavior data only available through the use of the simulation. In particular, inputs supplied the test generator define specific hardware functionalities to be tested. The resulting test files the test generator gathers may be subsequently utilized to better understand various aspects of the simulated target processor's core.

By modeling the processor core, simulation is able to provide an accurate model that allows each aspect of the simulated processor core's behavior to match that of a specific target processor core. As a result, simulations can provide visibility that translates into detailed information regarding each aspect of the target processor core's execution behavior. Simulators are not without limitations, however. Generating the test cases required to exercise the target processor core can be a laborious and time consuming task. Further, the problems associated with test case generation are particularly acute with target processor cores that employ multithreaded processing techniques.

### SUMMARY

A system and method are disclosed that provide for generating a test case operable to test a circuit design using a plurality of threads. In one embodiment, a test code and state initialization engine, responsive to a random number sequence and a probability profile, generates test code. A distribution settings engine generates default distribution settings that specify a magnitude of at least one simulation parameter for each thread based on a default probability distribution profile. A knob-setting interface is included for optionally differentiating the default distribution settings. The optionally differentiated distribution settings are then associated with the test code in order to generate the test case that exercises a circuit design model of the circuit design.

### BRIEF DESCRIPTION OF THE DRAWINGS

FIG. 1 depicts a block diagram of an embodiment of a system for simulating target processor core models that can be exercised by an Automatic Test Generator (ATG);

FIG. 2 depicts a block diagram of an embodiment of a system for testing a circuit design using an ATG that is operable to generate a test case in accordance with the teachings described herein;

FIG. 3 depicts a block diagram of an embodiment of a system for generating a test case; and

FIG. 4 depicts a flow chart of an embodiment of a method of generating a test case.

### DETAILED DESCRIPTION OF THE DRAWINGS

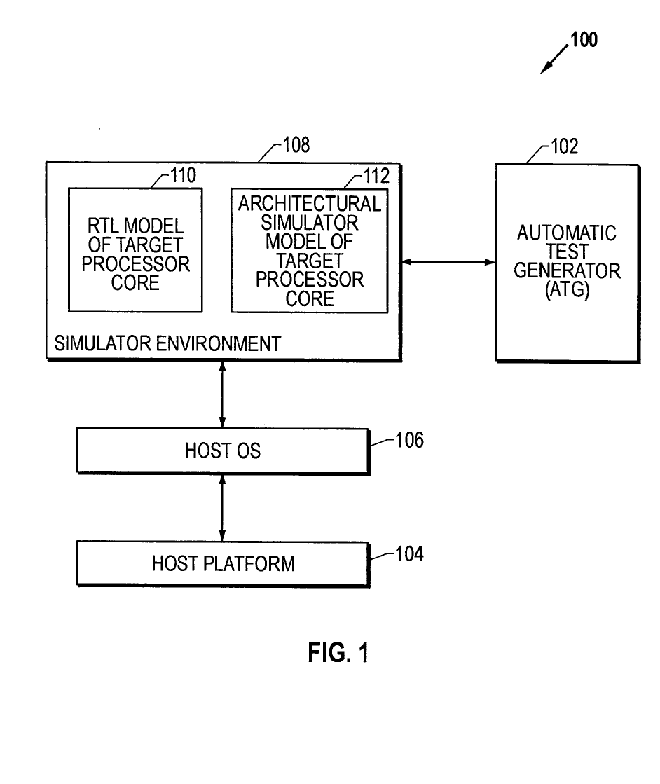

In the drawings, like or similar elements are designated with identical reference numerals throughout the several views thereof, and the various elements depicted are not necessarily drawn to scale. Referring now to FIG. 1, therein is depicted an embodiment of a system 100 for simulating target processor core models that can be exercised by an Automatic Test Generator (ATG) 102. A host platform 104 includes a host OS 106 executing thereon that is operable to provide a software platform. A simulator environment 108 is provided as a software rendition capable of running on the host OS 106, and may be embodied as one or more simulated target instances that define a simulated environment. As illustrated, the simulator environment includes a Register-Transfer Level (RTL) model 110 of a target processor core capable of parallel instruction processing, i.e., multi-threading, and an architectural simulator model 112 of the same target processor core. As will be explained in further detail hereinbelow, the ATG 102, responsive to input settings, generates a test case that exercises the behaviors and functionalities of the RTL model 110 and the architectural simulator model 112. The resulting test files are then utilized to understand the behavior of the target processor core.

The RTL model 110 and the architectural simulator model 112 may simulate any processor core having any configuration or digital design. For example, the target processor core may simulate a two-core processor system that delivers high availability and scalability with a wide breadth of enterprise application capabilities. It should be appreciated that depending on the design and verification objectives, the simulator environment 108 may include other types of target processor core models.

The RTL model 110 simulates the target processor core by utilizing a hardware-description language (HDL) that specifies the signal and gate-level behavior of the target processor core. The architectural simulator model 112, on the other hand, provides a higher level of abstraction than the RTL simulator model 110 in order to model the target processor core in terms of a high-level architecture that defines system-level behavioral functionalities of the target processor core. The RTL model 110 may be designed with the aid of computer-aided design (CAD) software tools, also referred to as computer-aided engineering (CAE) software tools, that assist in the development of the conceptual and physical design of the IC as well as the verification of the IC.

Sophisticated CAD software tools contain component libraries and component models that describe in detail the logical and electrical operations of the digital system design of the IC. Using these models, the IC design may be verified so that various types of logic and timing errors may be found by the test generator during the pre-silicon simulation phase of development. Specifically, the RTL model 110 may be designed by a schematic editor in a highly capable HDL environment such as a Very High Speed Integrated Circuit (VHSIC) hardware description language (VHDL) environment, a Verilog description language environment, or an Advanced Boolean Equation Language (ABEL) environment, for example. The HDL language environment provides a design, simulation, and synthesis platform wherein each constituent component within the design can be provided with both a well-defined interface for connecting it to other components and a precise behavioral specification that enables simulation. The architectural model 112, on the other hand, may be implemented in a higher-level language such as C or C++.

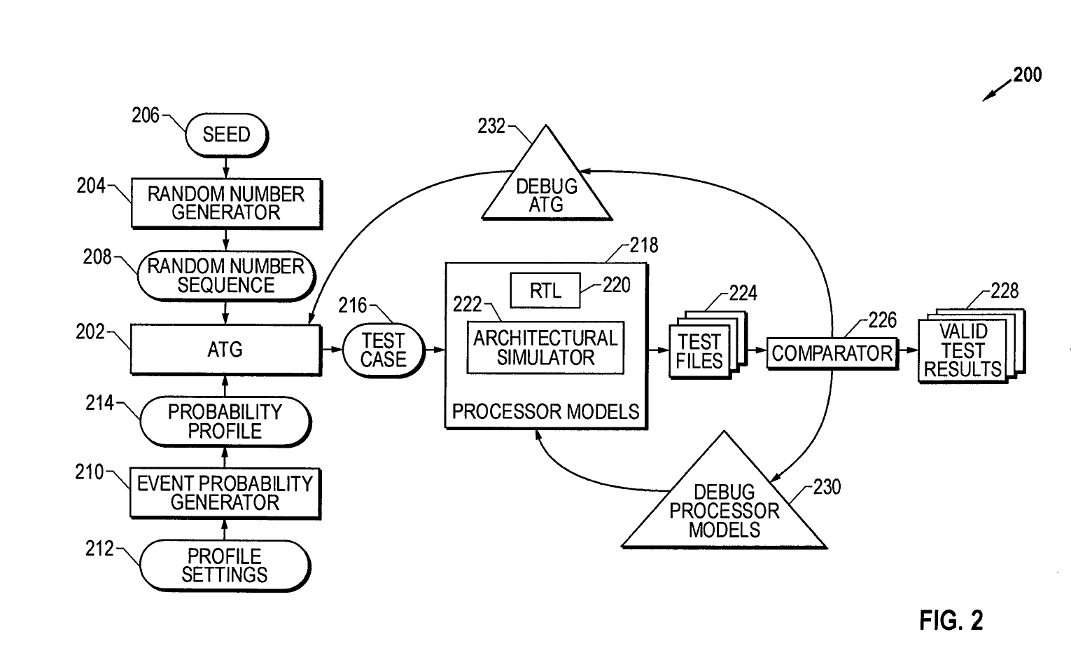

FIG. 2 depicts a system 200 for testing a circuit design using an ATG 202 that is operable to generate a test case according to one embodiment of the invention. A random number generator 204, responsive to a seed 206, generates a random number sequence 208. In one embodiment, if the seed is a number A, the random number generator 204 generates the random number sequence 208 {A₁, A₂, A₃, . . . , A}. By way of another example, if the seed 206 provided to the random number generator 204 is B, then the random number sequence 208 generated is {B₁, B₂, B₃, . . . , Bₘ}. Hence, the random number sequence 208 may be considered a function of the seed 206. In another embodiment, the random number sequence 208 may be considered a random sequence of numbers that are “predetermined” based upon the seed 206.

An event probability generator 210, responsive to profile settings 212, generates a probability profile 214. The profile settings 212 are user configurable settings which define the frequency or occurrence of the events that will exercise the processor models. Events include data operations such as loading, storing, and arithmetic operations, for example. Moreover, events include other performance-based operations such as the selection of parameters related to floating-point representations of numbers. The event probability generator 210 reconstitutes the profile settings 212 into the probability profile 214 which defines a set of event-related parametrics that will be accepted by the ATG 202. The ATG 202, responsive to the random number sequence 208 and the probability profile 204, generates a test case 216 in order to exercise the processor models 218. Additionally, command line settings may also be provided in the generated test case 216 which relate to the starting and stopping of specific actions in the processor models 218 and the defining of testing conditions, such as the number of threads, for example.

Command line settings are particularly important for exercising RTL model 220 and architectural simulator model 222 using multithreaded test cases. As alluded to earlier, multithreaded processing provides an execution resource that may be applied to solve problems effectively and efficiently via concurrent processing. In order to properly exercise multithreaded test cases in applicable processor models, the ATG 202 generates command line settings that include probability distribution profile settings that specify the manner in which different threads of the test case are to be exercised by the processor models 218. The probability distribution profile settings specify the magnitude of at least one simulation parameter on a per thread basis, which may relate to the amount of data operations such as loading, storing, and arithmetic operations, or performance-based operations such as the number of instructions or floating point representations. For example, in one embodiment, the probability distribution profile settings specify a decomposition of instructions that indicates the number of instructions each thread is allocated during the exercise. By way of another example, the probability distribution profile settings may specify the ratio of load-to-store operations on a per thread basis.

As illustrated, the test case 216 exercises the RTL model 220 and the architectural simulator model 222 and the results of the exercises are stored as test files 224. A comparator 226, which may be a programmer, a group of programmers, an expert system, or a combination thereof, examines the content of test files 224 to determine if the test results are valid or invalid. In particular, the comparator 226 examines and compares the results provided by the RTL model 220 and the results provided by the architectural simulator model 222. As previously discussed, the RTL model 220 simulates register-level events in the target processor core. The RTL model, therefore, serves as a verification tool for the architectural simulator 222. Additionally, the comparator 226 examines the output provided by the RTL model 220 and the architectural simulator 222 to determine if an illegal test behavior has occurred.

If the test files are valid, i.e., the RTL model 220 verifies the architectural simulator model 222 and the test files 224 do not contain illegal test behavior, the test files 224 become valid test results 228 which provide detailed information regarding each exercised aspect of the target processor core's execution behavior. On the other hand, if the test files 224 indicate processor model inconsistences between the RTL model 220 and architectural simulator 222, then a debugging operation 230 may be required with respect to the processor models. Debugging the architectural simulator and RTL models may involve diagnosing and resolving the problem according to conventional techniques. For example, by examining the test case 216, test files 224, and underlying HDL-based code of the RTL model 220, a clear understanding of the symptoms of the problem may be achieved. Then all of the variables that affect the problem may be identified and the variables progressively eliminated until the root cause of the problem is isolated. Once the root cause is isolated, the HDL-based code of the models may be appropriately modified to eliminate the problem. Further information relative to debugging the processor models may be found in the aforementioned patent application entitled: “System and Method for Building a Test Case Including a Summary of Instructions,” filed ______ application Ser. No. ______ (Docket Number 200208930-1), in the names of Ryan C. Thompson, John W. Maly, and Adam C. Brown, which is hereby incorporated by reference for all purposes. If the test files 224 indicate the presence of an illegal test behavior, however, the ATG 202 requires a debugging operation 232 as described more fully in the following co-pending patent application: “System and Method for Testing a Circuit Design,” filed ______, application Ser. No. ______ (Docket Number 200209135-1), in the names of Ryan C. Thompson, John W. Maly, and Zachary S. Smith, which is hereby incorporated by reference for all purposes.

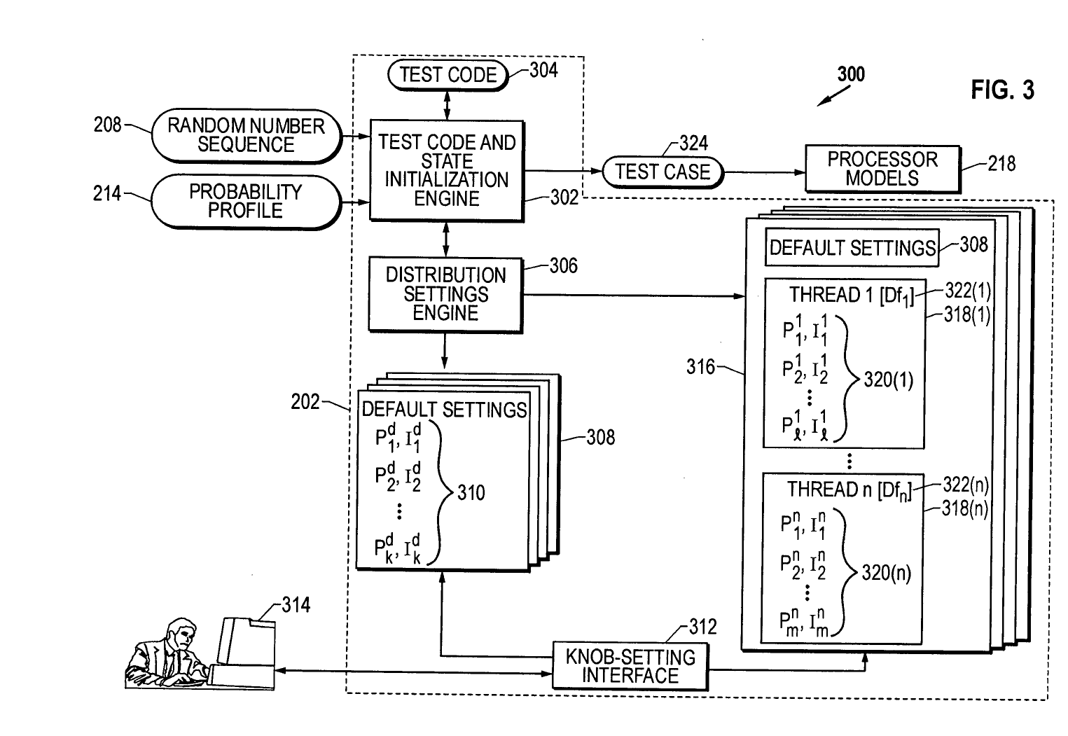

FIG. 3 depicts an embodiment of a system 300 for generating a multithreaded test case 324. The random number sequence 208 and probability profile 214 are provided to a test code and state initialization engine 302 which forms a portion of the ATG 202. In response to the random number sequence 208 and the probability profile 214, the test code and state initialization engine 302 generates test code 304 which includes the state initialization. The test code 304 includes the sequence of the events that will exercise the processor models 218 and includes the state initialization instructions which appropriately set all the counters, addresses, and storage medium contents, for example, to initial predetermined values. A distribution settings engine 306, which is associated with the ATG 202, is in communication with the test code and state initialization engine 302 in order to generate distribution settings that designate the event flow with respect to the multiple threads. In particular, the distribution settings engine 306 specifies probability distribution settings or “knobs” for the multiple threads. Initially, the distribution settings engine 306 generates default distribution settings 308 that specify a default probability distribution profile 310 that applies to each of the multiple threads. As illustrated, the default probability distribution profile 310 establishes the following values for a default knob, d:
dεD={(P^{d}₁, I^{d}₁), (P^{d}₂, I^{d}₂) . . . , (P^{d}ₖ, I^{d}ₖ)} such that
ΣP^{d}ᵢ=1 for i=1 through i=k, wherein
D is the set of all default knobs d; and
P^{d} is a default probability factor that expresses the probability of a thread being assigned a corresponding magnitude of at least one simulation parameter I^{d}. The sum of the probabilities of P^{d}₁ through P^{d}ₙ equals one as indicated by the summation expression.

For example, the default probability distribution profile 310 may have the following implementation in one embodiment:

```
knob def_num_instructions {
#thread default
  50%  20
  50%  40
}
```

In the implementation entitled knob def_num_instructions, i.e., a number of default knob settings that define assignment of instructions per thread, the following values are indicated:
dεD={(0.5, 20),(0.5, 40)}, wherein:
P^{d}₁=0.5,
I^{d}₁=20,
P^{d}₂=0.5, and
I^{d}₂=40.

Accordingly, the default probability distribution profile indicates that each thread has a 50% probability of processing 20 instructions per event cycle and a 50% probability of processing 40 instructions per event cycle.

The default distribution settings 308 may be optionally differentiated via a knob-setting interface 312, which is associated with ATG 202, that may take the form of a Graphical User Interface (GUI). The knob-setting interface 312 presents the default probability settings 310 to a logical entity, illustrated as a computer station/programmer 314. It should be appreciated, however, that the logical entity may take other forms such a group of programmers or an expert system, for example. The optional differentiation of the default distribution settings 308 via knob-setting interface 312 provides a mechanism for optionally configuring the default distribution settings 308 by selectively accepting the settings, partially modifying the settings, or overriding the settings. Using the systems and methods described herein, the time and labor associated with generating the test cases for target processor cores utilizing multithreaded processing techniques is greatly reduced as the distribution settings engine builds a portion of the required input data for the test cases, i.e., the distribution settings in a user-friendly knob-configuration environment that supports automatic generation of different knobs.

Optionally configured distribution settings 316, the result of the programmer's optional differentiation, can include at least a portion of the default settings 308, and thread-specific override settings illustrated as Thread-1 distribution settings 318(1) through Thread-n distribution settings 318(n). With respect to Thread-1 distribution settings 318 (1), an override distribution factor 322 (1), Df₁, expresses the portion of time for which a Thread-1 specific probability distribution profile 320(1) is being utilized. In particular, 0≦Df_{1≦1} and the probability of the default distribution settings, Df_{d}, being utilized with respect to Thread-1 is represented as Df_{d}=1−Df₁.

As illustrated, the Thread-1 probability distribution profile 320 (1) establishes the following values for a Thread-1 knob, t₁:
t₁εT₁={(P¹₁, I¹₁), (P¹₂, I¹₂), . . . , (P¹₁, I¹₁)} such that
ΣP¹ᵢ=1 for i=1 through i=l, wherein
T₁ is the set of all Thread-1 specific knobs t₁; and
P¹ is a user-selected probability factor (i.e., knob setting) that expresses the probability at which a corresponding magnitude of at least one simulation parameter I¹ will be assigned as part of Thread-1.

Similarly, Thread-n distribution settings 320(n) include an override distribution factor 322(n), Dfₙ, which expresses the portion of time for which Thread-n specific probability distribution settings 320(n) are utilized. As illustrated, the Thread-n probability distribution profile 320(n) establishes the following values for a Thread-n knob, tₙ:
tₙεTₙ{(Pⁿ₁, Iⁿ₁), (Pⁿ₂, Iⁿ₂), . . . , (Pⁿₘ, Iⁿₘ)} such that
ΣPⁿᵢ=1 for i=1 through i=m, wherein
Tₙ is the set of all Thread-n specific knobs tₙ; and
Pⁿ is a user-selected probability factor (i.e., knob setting) that expresses the probability at which a corresponding magnitude of at least one simulation parameter Iⁿ will be assigned as part of Thread-n.

For example, in a target processor model being exercised by a test case with four threads, the optionally configured distribution settings 316 may have the following implementation:

```
knob op_con_num_instructions {
#thread default
  50%  20
  50%  40
#thread 1 3 50%
  100%  75
#thread 4 100%
  40%  10
  60%  5
}
```

In the implementation entitled knob op_con_num_instructions, i.e., a number of optionally configured knob instructions, the following values are indicated:
dεD={(0.5, 20), (0.5, 40)}, wherein:
P^{d}_{1=0.5,}
I^{d}_{1=20,}
P^{d}_{2=0.5}, and
I^{d}_{2=40.}
   t₁, t₃εT₁={(1, 75)}, wherein:
P¹₁₌₁, and
I¹₁=75.
   t₄εT₄{(0.4, 10), (0.6, 5)}, wherein:
P⁴₁=0.4,
I⁴₁=10,
P⁴₂=0.6, and
I⁴₂=5.

Accordingly, in the illustrative test case embodiment having four threads, threads 1-4, for thread 1, the default probability distribution profile D will be applied 50% of the time and the thread 1 specific probability distribution profile will be applied 50% of the time as Df₁=50%. As a result, thread 1 has a 25% probability of processing 20 instructions, a 25% probability of processing 40 instructions, and a 50% probability of processing 75 instructions in a test case. Further, as indicated by the expression t₁, t₃ εT₁, threads 1 and 3 share a specific probability distribution profile. Therefore, thread 3 has the same distribution as thread 1.

For thread 2, as no thread-specific probability distribution profile was configured by the programmer, the default probability distribution profile is applied 100% of the time. Accordingly, thread 2 has a 50% probability of processing 20 instructions and a 50% probability of processing 40 instructions in a test case. For thread 4, the thread-specific distribution factor, Df₄, equals 100% in order to override the default probability distribution settings. Accordingly, thread 4 has a 40% probability of processing 10 instructions and a 60% probability of processing 5 instructions.

The optionally configured distribution settings 316 described hereinabove are associated with the test code 304 in order to generate the test case 324 for exercising the circuit design model of the circuit design, i.e., processor models 218. In one embodiment, the optionally configured distribution settings 316 are embedded in the test case 324 and the test files 224 for analysis. In particular, the distribution settings 316 may form a portion of the command line settings or other code associated with the test case and test files. Accordingly, the systems and methods described herein facilitate the preparation of test cases required to exercise the target processor core by automatically providing knob settings in the form of a default probabilistic distribution profile that may be optionally configured into a user-defined probabilistic distribution profile on a per-thread basis. It should be appreciated that although in each of the aforementioned examples the threads were optionally differentiated based on the number of instructions (operating as the selected simulation parameter), other simulation parameters such as loading vs. storing instructions, arithmetic operations, and floating-point operations may also be used for differentiating the threads using the knob-setting system and method described hereinabove.

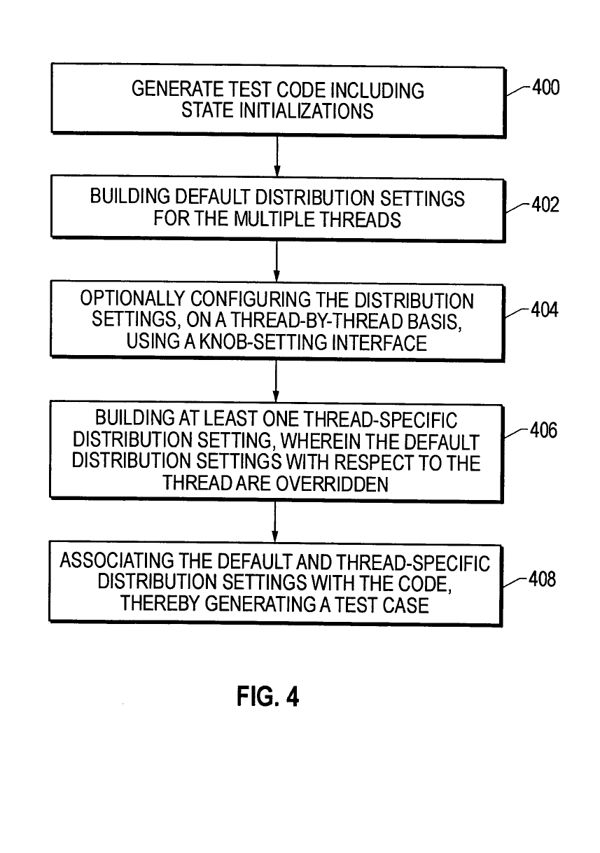

FIG. 4 depicts an embodiment of a method of generating a test case operable to test a circuit design using a plurality of threads. At block 400, test code including state initializations is generated. The test code may be based upon a random number sequence supplied by a random number generator, a probability profile supplied by an event probability generator, and command line settings. At block 402, default distribution settings are built for the multiple threads. In one embodiment, the default distribution settings are based on a default probability distribution profile and may specify, for example, the number of instructions, the ratio of load and store instructions, or any other magnitude of at least one simulator parameter applied to each of the plurality of threads. At block 404, the distribution settings are optionally configured using a knob-setting interface, which may take the form of a GUI, on a thread-by-thread basis. At block 406, at least one thread-specific distribution setting is built which specifies on a thread-by-thread basis the number of instructions applied thereto based on a user-defined probabilistic distribution profile. As set forth above, the thread-specific distribution settings operate to override the default distribution settings with respect to the specific threads selected at block 404. At block 408, the default and thread-specific distribution settings are associated with the test code, thereby generating a multithreaded test case with appropriately differentiated knob settings.

Although the invention has been particularly described with reference to certain illustrations, it is to be understood that the forms of the invention shown and described are to be treated as exemplary embodiments only. Various changes, substitutions and modifications can be realized without departing from the spirit and scope of the invention as defined by the appended claims.

1. A system for generating a test case operable to test a circuit design using a plurality of threads, comprising:
a test code and state initialization engine operating responsive to a random number sequence and a probability profile for generating test code;
a distribution settings engine for generating default distribution settings that specify a magnitude of at least one simulation parameter assigned to each of said plurality of threads based on a default probability distribution profile; and
a knob-setting interface for optionally differentiating said default distribution settings,
wherein said optionally differentiated distribution settings are associated with said test code in order to generate said test case for exercising a circuit design model of said circuit design.

2. The system as recited in claim 1, wherein said optionally differentiated distribution settings comprise settings that specify on a thread-by-thread basis a magnitude of at least one simulation parameter based on a user-defined probabilistic distribution profile.

3. The system as recited in claim 1, wherein said at least one simulation parameter is selected from a group of parametric variables consisting of number of instructions, loading operations, storing operations, arithmetic operations, and floating-point operations.

4. The system as recited in claim 1, wherein said test case is operable to exercise said circuit design model with events selected from the group consisting of loading operations, storing operations, arithmetic operations, and floating-point operations.

5. The system as recited in claim 1, wherein said circuit design model comprises a multiprocessor core model.

6. The system as recited in claim 1, wherein said circuit design model comprises a register-transfer level (RTL) model of an integrated circuit.

7. The system as recited in claim 1, wherein said circuit design model comprises an architectural simulation model of an integrated circuit.

8. The system as recited in claim 1, wherein said knob-setting interface is operable to be utilized by a logical entity selected from the group consisting of a programmer, a group of programmers, and an expert system.

9. The system as recited in claim 1, wherein said knob-setting interface comprises a Graphical User Interface (GUI).

10. The system as recited in claim 1, wherein said distribution settings engine is implemented in a software language selected from the group consisting of C, C++, and Perl.

11. A method for generating a test case operable to test a circuit design using a plurality of threads, comprising:
generating test code including state initializations;
building default distribution settings for said multiple threads;
optionally differentiating said default distribution settings, on a thread-by-thread basis, using a knob-setting interface;
building at least one thread-specific distribution setting, wherein said default distribution settings with respect to a specific thread are overridden; and
associating said default and thread-specific distribution settings with said test code, thereby generating a test case for exercising a circuit design model of said circuit design.

12. The method as recited in claim 11, wherein the operation of generating test code comprises generating test code including state initializations based upon a random number sequence supplied by a random number generator.

13. The method as recited in claim 11, wherein the operation of generating test code comprises generating test code including state initializations based upon a probability profile supplied by an event probability generator.

14. The method as recited in claim 11, wherein the operation of building default distribution settings comprises assigning a magnitude of at least one simulation parameter for each of said plurality of threads based on a default probability distribution profile.

15. The method as recited in claim 14, further comprising selecting said at least one simulation parameter from a group of parametric variables consisting of number of instructions, loading operations, storing operations, arithmetic operations, and floating-point operations.

16. The method as recited in claim 11, wherein the operation of optionally differentiating said distribution settings comprises providing thread-specific distribution settings via a Graphical User Interface (GUI) that operates as said knob-setting interface.

17. The method as recited in claim 11, wherein the operation of building at least one thread-specific distribution setting further comprises specifying on a thread-by-thread basis a magnitude of at least one simulation parameter based on a user-defined probabilistic distribution profile.

18. A computer-readable medium operable with a computer platform to generate a test case for testing a circuit design using a plurality of threads, the medium having stored thereon:
instructions for generating test code including state initializations;
instructions for building default distribution settings for said multiple threads;
instructions for presenting a knob-setting interface that enables optional differentiation of said distribution settings;
instructions for overriding said default distribution settings with at least one thread-specific distribution setting generated via said knob-setting interface; and
instructions for associating said default and thread-specific distribution settings with said test code, thereby generating a test case for executing a circuit design model of said circuit design.

19. The computer-readable medium as recited in claim 18, wherein said instructions for generating test code comprises instructions for generating test code including state initializations based upon a random number sequence supplied by a random number generator.

20. The computer-readable medium as recited in claim 18, wherein said instructions for generating test code comprises instructions for generating test code including state initializations based upon a probability profile supplied by an event probability generator.

21. The computer-readable medium as recited in claim 18, wherein said instructions for building default distribution settings comprises instructions for assigning a number of commands for each of said plurality of threads based on a default probability distribution profile.

22. The computer-readable medium as recited in claim 18, wherein said instructions for presenting a knob-setting interface comprise instructions for providing a user a Graphical User Interface (GUI) that enables inputting of thread-specific knob settings.

23. A system for generating a test case operable to test a circuit design using a plurality of threads, comprising:
means for generating test code including state initializations;
means for building default distribution settings for said multiple threads;
means for optionally differentiating said distribution settings on a thread-by-thread basis;
means for building at least one thread-specific distribution setting, wherein said default distribution settings with respect to a specific thread are overridden; and
means for associating said default and thread-specific distribution settings with said test code, thereby generating a test case for exercising a circuit design model of said circuit design.

24. The system as recited in claim 23, wherein said means for generating test code comprises means for generating test code including state initializations based upon a random number sequence supplied by a random number generator.

25. The system as recited in claim 23, wherein said means for generating test code comprises means for generating test code including state initializations based upon a probability profile supplied by an event probability generator.

26. The system as recited in claim 23, wherein said means for building default distribution settings comprises means for assigning a magnitude of at least one simulation parameter for each of said plurality of threads based on a default probability distribution profile.

27. The system as recited in claim 26, wherein said at least one simulation parameter is selected from a group of parametric variables consisting of number of instructions, loading operations, storing operations, arithmetic operations, and floating-point operations.

28. The system as recited in claim 23, wherein said means for optionally differentiating said distribution settings comprises means for providing thread-specific distribution settings via a Graphical User Interface (GUI) that operates as a knob-setting interface.

29. The system as recited in claim 23, wherein said means for building at least one thread-specific distribution setting comprises means for specifying on a thread-by-thread basis a magnitude of at least one simulation parameters based on a user-defined probabilistic distribution profile.

30. A computer system operable to simulate a platform for testing a circuit design using multiple threads, the computer system comprising:
a random number generator, operating responsive to a seed, for generating a random number sequence;
an event probability generator, operating responsive to profile settings, for generating a probability profile;
a test generator for generating default distribution settings that specify a magnitude of at least one simulation parameter for each of said multiple threads based on a default probability distribution profile; and
a knob-setting interface for optionally differentiating said default distribution settings,
wherein said test generator generates a test case based upon said random number sequence, said probability profile, and said optionally differentiated distribution settings, said test case for exercising a circuit design model of said circuit design.

31. The computer system as recited in claim 30, wherein said knob-setting interface comprises a Graphical User Interface (GUI).

32. The computer system as recited in claim 30, wherein said circuit design model comprises a register-transfer level (RTL) model of an integrated circuit.

33. The computer system as recited in claim 30, wherein said circuit design model comprises an architectural simulation model of an integrated circuit.

34. The computer system as recited in claim 30, wherein said test generator is implemented in a software language selected from the group consisting of C, C++, and Perl.
